(19) United States
(12) Patent Application Publication
(10) Pub. No.: US 2026/0276571 A1
(43) Pub. Date: Sep. 17, 2026

(54) CHARACTERIZING PORE SIZE DISTRIBUTION BY INTEGRATING NMR AND ACOUSTIC MEASUREMENTS

(71) Applicant: Schlumberger Technology Corporation, Sugar Land, TX (US)

(72) Inventors: Juntao Ma, Beijing (CN); Xinyi Lu, Beijing (CN); Lin Liang, Cambridge, MA (US); Mohammed Fadhel Al-Hamad, Dhahran (SA); Marie Van Steene, Dhahran (SA); Olivier Sindt, Cambridge (GB); Shouxiang Mark Ma, Dhahran (SA)

(21) Appl. No.: 19/569,139

(22) Filed: Mar. 17, 2026

Related U.S. Application Data
(60) Provisional application No. 63/773,217, filed on Mar. 17, 2025.

(51) Int. Cl. G01N 24/08; G01R 33/50; G01V 3/32; G01V 3/38

(52) U.S. Cl. CPC G01N 24/081; G01R 33/50; G01V 3/32; G01V 3/38

(57) ABSTRACT

A method may include receiving transverse relaxation time (T₂) distribution data associated with a geological formation, the T₂ distribution data being acquired by a nuclear magnetic resonance (NMR) tool. The method may also involve decomposing the T₂ distribution data into Gaussian distributions using inversion techniques, computing reconstructed acoustic values associated with the geological formation based on a first Gaussian distribution and a first pore type, receiving measured acoustic values associated with the geological formation, determining that the first pore type corresponds to the first Gaussian distribution based on the one or more reconstructed acoustic values and the one or more measured acoustic values, and in response to determining that the first pore type corresponds to the first Gaussian distribution, determining a pore size distribution (PSD) for the first Gaussian distribution based on an aspect ratio associated with the first pore type.

### CROSS REFERENCE TO RELATED APPLICATION

This application claims priority to and the benefit of U.S. Provisional Patent Application No. 63/773,217, filed on Mar. 17, 2025, entitled, “IMPROVED PORE SIZE DISTRIBUTION FROM NMR T2 BY INTEGRATING ASPECT RATIO AND SONIC MEASUREMENTS,” which is hereby incorporated by reference in its entirety for all purposes.

### BACKGROUND

The present disclosure generally relates to characterizing pore systems. More specifically, the present disclosure relates to determining pore size distribution in geological formations.

Pore size distribution may provide insight into a range and proportion of pore sizes within geological formations. The pore size distribution may assist in determining the permeability, hydrocarbon recoverability, capillary pressure behavior, water saturation, and the like of the geological formation or rock types within the geological formation. However, the pore systems in geological formations are often complex and may consist of multiple pore types with a range of aspect ratios. As such, characterizing the pore size distribution is challenging.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light and not as admissions of prior art.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

A method may include receiving, via a processing system, transverse relaxation time (T₂) distribution data associated with a geological formation, wherein the T₂ distribution data is acquired by a nuclear magnetic resonance (NMR) tool; decomposing, via the processing system, the T₂ distribution data into one or more Gaussian distributions using one or more inversion techniques; computing, via the processing system, one or more reconstructed acoustic values associated with the geological formation based on a first Gaussian distribution of the one or more Gaussian distributions and a first pore type; receiving, via the processing system, one or more measured acoustic values associated with the geological formation, wherein the one or more measured acoustic values are acquired by one or more acoustic tools; determining, via the processing system, that the first pore type corresponds to the first Gaussian distribution based on the one or more reconstructed acoustic values and the one or more measured acoustic values; and in response to determining that the first pore type corresponds to the first Gaussian distribution, determining, via the processing system, a pore size distribution (PSD) for the first Gaussian distribution based on an aspect ratio associated with the first pore type.

A system may include a computing system configured to perform operations comprising: receiving transverse relaxation time (T₂) distribution data associated with a geological formation, wherein the T₂ distribution data is acquired by a nuclear magnetic resonance (NMR) tool; decomposing the T₂ distribution data into one or more Gaussian distributions using one or more inversion techniques; computing one or more reconstructed acoustic values associated with the geological formation based on a first Gaussian distribution of the one or more Gaussian distributions and a first pore type; receiving one or more measured acoustic values associated with the geological formation, wherein the one or more measured acoustic values are acquired by one or more acoustic tools; determining that the first pore type corresponds to the first Gaussian distribution based on the one or more reconstructed acoustic values and the one or more measured acoustic values; and in response to determining that the first pore type corresponds to the first Gaussian distribution, determining a pore size distribution (PSD) for the first Gaussian distribution based on an aspect ratio associated with the first pore type.

A non-transitory computer-readable medium may include computer-executable instructions that, when executed, are configured to cause a processing system to perform operations comprising: receiving transverse relaxation time (T₂) distribution data associated with a geological formation, wherein the T₂ distribution data is acquired by a nuclear magnetic resonance (NMR) tool disposed; decomposing the T₂ distribution data into one or more Gaussian distributions using one or more inversion techniques; computing one or more reconstructed acoustic values associated with the geological formation based on a first Gaussian distribution of the one or more Gaussian distributions and a first pore type; receiving one or more measured acoustic values associated with the geological formation, wherein the one or more measured acoustic values are acquired by one or more acoustic tools; determining that the first pore type corresponds to the first Gaussian distribution based on the one or more reconstructed acoustic values and the one or more measured acoustic values; and in response to determining that the first pore type corresponds to the first Gaussian distribution, determining a pore size distribution (PSD) for the first Gaussian distribution based on an aspect ratio associated with the first pore type.

The brief summary presented above is intended only to familiarize the reader with certain aspects and contexts of embodiments of the present disclosure without limitation to the claimed subject matter.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 illustrates a tool system that may employ the systems and methods of this disclosure, in accordance with embodiments presented herein;

FIG. 2 illustrates an example elliptical tube model, in accordance with embodiments presented herein;

FIG. 3 illustrates a graph of a synthetically generated T₂ distribution and 64 T2 bins, in accordance with embodiments presented herein;

FIG. 4 illustrates graphs that depict effects of assigning different aspect ratios (ARs) on the pore size distribution (PSD) derived from T₂ distribution, in accordance with embodiments presented herein;

FIG. 5 illustrates a flow chart of a method for decomposing the T₂ distribution into one or more Gaussian distributions, in accordance with embodiments presented herein;

FIG. 6A illustrates an example curve that corresponds to a T2 distribution for a rock formation, in accordance with embodiments presented herein;

FIG. 6B illustrates example T₂ distribution segments of the T2 distribution illustrated in FIG. 6A, in accordance with embodiments presented herein;

FIG. 7 illustrates a graph of individual PSDs for reference pores and stiff pores from assigned Gaussian distributions depicted in FIG. 6B, in accordance with embodiments presented herein; and

FIG. 8 illustrates a flow chart of a method for determining individual PSDs for pore systems in a multimodal pore network, in accordance with embodiments presented herein.

### DETAILED DESCRIPTION

Certain embodiments commensurate in scope with the present disclosure are summarized below. These embodiments are not intended to limit the scope of the disclosure, but rather these embodiments are intended only to provide a brief summary of certain disclosed embodiments. Indeed, the present disclosure may encompass a variety of forms that may be similar to or different from the embodiments set forth below.

As used herein, the term “coupled” or “coupled to” may indicate establishing either a direct or indirect connection (e.g., where the connection may not include or include intermediate or intervening components between those coupled), and is not limited to either unless expressly referenced as such. The term “set” may refer to one or more items. Wherever possible, like or identical reference numerals are used in the figures to identify common or the same elements. The figures are not necessarily to scale and certain features and certain views of the figures may be shown exaggerated in scale for purposes of clarification.

As used herein, the terms “inner” and “outer”; “up” and “down”; “upper” and “lower”; “upward” and “downward”; “above” and “below”; “inward” and “outward”; and other like terms as used herein refer to relative positions to one another and are not intended to denote a particular direction or spatial orientation. The terms “couple,” “coupled,” “connect,” “connection,” “connected,” “in connection with,” and “connecting” refer to “in direct connection with” or “in connection with via one or more intermediate elements or members.”

Furthermore, when introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment,” “an embodiment,” or “some embodiments” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

Pore-size distribution (PSD) may be used to characterize pore systems in geological formations within the earth. In some embodiments, nuclear magnetic resonance (NMR) transverse relaxation time (T₂) distribution may be used to derive the PSD by applying a single aspect ratio (AR or α) value of 1.0. The aspect ratio may describe the shape of the pores within a respective portion of the geological formation. An aspect ratio value of 1.0 may assume that the pores within the portion of the geological formation is circular or round. As a result, PSD derived by this type of analysis often describes the pore network with a single distribution. However, in subsurface formations such as carbonate formations, the pore system may be more complex and may consist of multiple pore types with different ARs, such as reference pores (e.g., interparticle pores) with elliptical shapes (e.g., AR ~0.3-0.5), stiff pores (e.g., moldic and vuggy pores) with an AR close to 1.0, and crack pores (e.g., microcracks and microfractures) with AR values of less than 0.1, such as those found in tight gas sand reservoirs. Since natural rocks such as carbonate rocks have diverse range of pore types in carbonates, characterizing the PSD in carbonate rocks becomes a challenging and intricate task. With this in mind, the present embodiments may quantify the effect of AR on T₂-derived PSD and then derive individual AR-driven PSDs for reference pores, stiff pores, crack pores in carbonate rocks, and the like.

Keeping the foregoing in mind, for monomodal pore systems, pore shape is considered when deriving PSD from the T₂ distribution. That is, the pore cross-section is assumed to be elliptical, and the semi-long axis (a) instead of the radius is derived from the corresponding T₂ transverse relaxation time and surface relaxivity (e.g., determined based on the T₂ transverse relaxation time). Each T₂ transverse relaxation time magnitude may then be normalized to calculate the probability density function (PDF) of area-based PSD (e.g., a-based PSD for given ARs).

For multimodal pore systems, however, the T₂ transverse relaxation time distribution (i.e., T₂ distribution) may first be separated into individual components using trough points, and adjacent components may be combined if they overlap with each other, such that they may be processed simultaneously. Each T₂ transverse relaxation time component may then be inverted separately into one or more Gaussian distributions, such that each component may represent reference pores, stiff pores, or crack pores. Based on the resulting combinations, a differential effective medium (DEM) model and Gassmann fluid substitution may be applied to obtained PSD with corresponding AR to calculate a corresponding reconstructed sonic slowness value. The reconstructed slowness may be compared with the measured slowness to identify a PSD with AR assignment combination that best fits the sonic measurements. As a result, individual a-based PSDs may be obtained for reference pores, stiff pores, and crack pores from T₂ by integrating AR and sonic measurements.

To validate the above methodology, synthetic T₂ transverse relaxation time distribution and sonic slowness may be generated based on given volume fractions and PSDs for reference pores, stiff pores, and crack pores. By comparing the synthetic data with that from measurements, it is noted that PSD derivation from T₂ transverse relaxation time distribution can be sensitive to AR. By decomposing the synthetic T₂ transverse relaxation time distribution into separate Gaussian distributions and assigning each to a specific pore type based on the synthetic sonic slowness values, the present embodiments may provide the correct individual PSD for each pore type.

As a result of employing the techniques described herein, the calculated volume fractions of reference pores, stiff pores, and crack pores may align with those obtained from core samples, thereby confirming that the derived individual PSDs for each pore type may provide improved accuracy in reservoir characterization, such as permeability estimation, and aid in designing mud systems with bridging agents and the like.

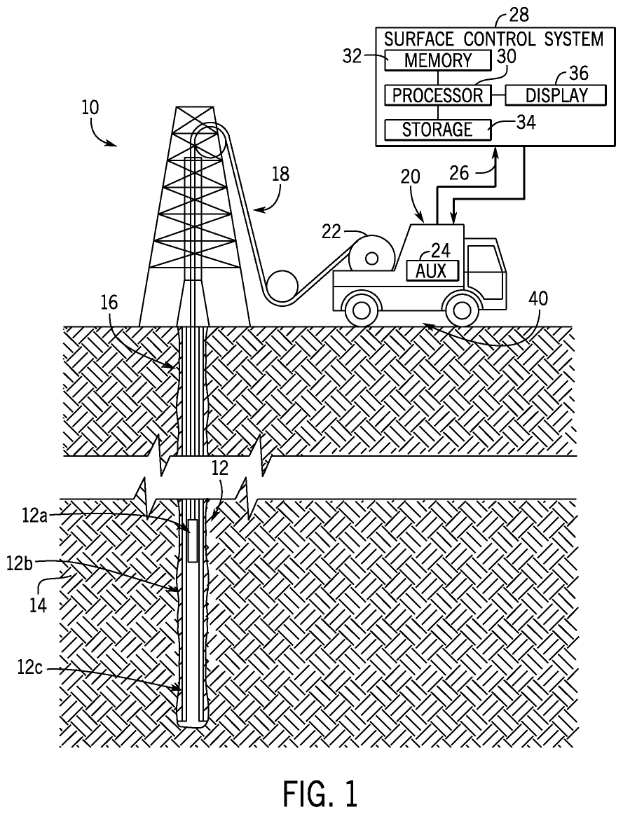

By way of introduction, FIG. 1 illustrates a tool system 10 (e.g., wireline, wireline service, combination of tools, wireline conveyance, logging system, intervention system, etc.) that may employ the systems and methods of this disclosure. The tool system 10 may be used to convey tools 12, through a geological formation 14 via a borehole 16. Any suitable number of tools may be used, and the tool system 10 is not limited to tools 12a, 12b, and 12c (e.g., collectively tools 12). In the example of FIG. 1, a downhole device having tools 12 may be conveyed on a cable 18 via a logging winch system (e.g., vehicle 20). Although the vehicle 20 is schematically shown in FIG. 1 as a mobile logging winch system carried by a truck, the vehicle 20 may be substantially fixed (e.g., a long-term installation that is substantially permanent or modular). In some embodiments, the tool system 10 may be used in an offshore unit (e.g., Independent-Leg Self-Elevating unit, Mat-Supported Self-Elevating, Column-Stabilized, Drillship, etc.). Any suitable cable 18 for well logging may be used. The cable 18 may be spooled and unspooled on a drum 22 and an auxiliary power source 24 may provide energy to the vehicle 20 and/or the tools 12.

In general, the tools 12a, 12b, and 12c are electrically coupled to receive a voltage supplied from the surface and/or a downhole power cartridge. For example, tools 12a, 12b, and 12c may correspond to power cartridges, hydraulic modules, rotary compensators, rotary power, bailers and the like. In some embodiments, the tools 12a, 12b, and 12c may be communicatively coupled to a surface control system 28 (e.g., software system, cloud-based software system, edge-based system.) For example, data signals 26 (e.g., uplink, downlink) may be transmitted from the surface control system 28 to one or more of the tools 12a, 12b, and 12c, and the data signals may be related to the sensor data, operating conditions data, operating parameters data, or any other desired data that may be returned to the surface control system 28 from the tools 12a, 12b, 12c. Additionally, the data signals 26 may include control signals, such as commands.

The surface control system 28 may be any electronic data processing system that can be used to carry out the systems and methods of this disclosure. For example, the surface control system 28 may include a processor 30, which may execute instructions stored in memory 32 and/or storage 34. As such, the memory 32 and/or the storage 34 of the surface control system 28 may be any suitable article of manufacture that can store the instructions. The memory 32 and/or the storage 34 may be read-only memory (“ROM”), random-access memory (“RAM”), flash memory, an optical storage medium, or a hard disk drive, to name a few examples. A display 36, which may be any suitable electronic display, may display images generated by the processor 30. The surface control system 28 may be a local component of the vehicle 20 (e.g., within the tool system 10), a remote device that analyzes data from other vehicles 20, a device located proximate to the wireline operation, or any combination thereof. In some embodiments, the surface control system 28 may be a mobile computing device (e.g., tablet, smart phone, or laptop), a server remote from the vehicle 20, and/or an edge server mounted on the vehicle. As shown in the illustrated embodiment, the surface control system 28 also includes a power supply 40 that is may be used to provide power to the tools 12a, 12b, 12c via the cable 18.

As described above, the tool system 10 may have any number or type of tools and is not limited to the three illustrated tools (e.g., the tool 12a, the tool 12b, and the tool 12b. In certain implements of the tool system 10, a tool 12a, 12b, and/or 12c may include a power cartridge, capable of providing power, motor control and/or logical control to other tools and/or components of the tool system 10. In some embodiments, the tool 12a, 12b and/or 12c may include sensors for formation and/or production measurements, a tractor for conveyance, or include mechanical mechanisms to operate completion control elements, such as sliding sleeves, safety valves, and the like. Notably, tools may be added, removed, and/or arranged in various ways to generate a desired service (e.g., function of the tool system 10). For example, one or more tools 12a, 12b, 12c may be arranged to perform a downhole tractor service, downhole slot cutting service, downhole shifting service, downhole milling service, downhole scale removal service, downhole debris removal service, downhole plug setting service, downhole tubing cutter service, downhole chemical jetting service, or the like.

In some embodiments, the tools 12 may include a nuclear magnetic resonance (NMR) tool that may use nuclear magnetic resonance to measure hydrogen in formation fluids with the geological formation 14. The measurement of hydrogen in the formation fluids may be used for determining the porosity, the pore size distribution, the fluid type (e.g., water, oil, gas), and the like associated with corresponding rock formations. By way of operation, the NMR tool may include permanent magnets that polarize hydrogen nuclei within formation fluids of the corresponding rock formations. The NMR tool may also include an antenna that transmits radiofrequency pulses that adjusts the spin of the hydrogen nuclei away from alignment with a magnetic field provided by the magnets. After the pulses stop, the hydrogen nuclei spin back to equilibrium, and the NMR tool measures longitudinal relaxation (T₁) and transverse relaxation (T₂). The transverse relaxation corresponds to the hydrogen nuclei (e.g., protons) losing phase coherence in the plane perpendicular to the magnetic field after being excited by a radiofrequency pulse in an NMR measurement. The transverse relaxation T₂ may be measured based on an amount of voltage induced in a receiver coil of the antenna as a function of time after the radiofrequency pulses are transmitted by the antenna. That is, the NMR tool may measure the voltages induced by hydrogen nuclei returning to its equilibrium state.

In addition, the tools 12 may include an acoustic tool that may transmit sound waves into the geological formation 14 and record reflected sound waves that interact or reflect off of various parts of the geological formation 14. The reflected sound waves may be measured by one or more receivers or sensors that may be positioned within the tools 12. The receivers may measure a travel time for the sound wave, wave attenuation, waveform shape, frequency characteristics of the wave, and the like. The acoustic tools may thus be used to monitor how acoustic waves travel within and off the geological formation 14 (e.g., layers of the geological formation) to determine formation velocity, mechanical properties, fractures, and cement quality of the geological formation 14, the borehole, and the like.

One or more tools 12a, 12b, 12c of a tool system 10 may include printed circuit boards (e.g., “PCBs”) that are adapted to perform one or more tasks. For example, one or more PCBs may be a primary PCBs which include processing functions (e.g., digital signal processing “DSP”), a microcontroller unit (e.g., “MCU”) and respective firmware for a respective tool 12a, 12b, 12c or a respective group of tools. That is, a primary PCB may perform functions for more than one tool 12a, 12b, 12c. Further, tool 12a, 12b, 12c may include secondary PCBs without processing functions or controlling functions and without firmware. One or more primary PCBs may function as a communication node (e.g., downhole communication node, hub server, proxy server) where the primary PCBs may communicate directly with the surface control system 28 (e.g. software system.) The primary PCB may also act as a data aggregator for the secondary PCBs, relaying data to the software system. In some embodiments, the primary PCB may also distribute commands (e.g., command mappings) downlinked by the surface control system 28.

With the foregoing in mind, the geological formation 14 may be characterized by pore size distribution (PSD), which may describe a range and proportion of pores sizes within the rock formations that make up the geological formation 14. Distributions of pore body sizes (PBSs), such as those derived from NMR tools, and pore throat sizes (PTSs) from mercury injection capillary pressure (MICP) may be some properties for characterizing the pore structure of the geological formation 14, as it governs the relationship between porosity and permeability, electrical and acoustic properties, distributions of water and oil, and the like.

NMR measurements acquired from NMR tools may be used to estimate PSD based on longitudinal relaxation time (T₁), longitudinal surface relaxivity (ρ₁), the surface area of the pore space (S), and the pore volume (V). Indeed, S/V corresponds to the surface area to volume ratio of the pore, and its inverse has the dimension of length, thereby yielding a measure of pore size, which may depend on a corresponding pore shape. Hence, PSD can be determined from T₁ distribution, as shown in Equation (1).

$$\frac{1}{{T}_{1}} = {ρ}_{1} \frac{S}{V} \qquad ( 1 )$$

Similarly, when bulk relaxation and diffusion effects are negligible compared to surface relaxation, pore size can be estimated from transverse relaxation time (T₂) based on transverse surface relaxivity (ρ₂), the surface area of the pore space (S), and the pore volume (V), as shown in Equation (2).

$$\frac{1}{{T}_{2}} = {ρ}_{2} \frac{S}{V} \qquad ( 2 )$$

Distributions of pore body sizes (PBSs), which may be derived from NMR measurements, and pore throat sizes (PTSs), which may be derived from mercury injection capillary pressure (MICP), are basic properties for characterizing the pore structure in porous media because it governs the relationship between porosity and permeability, electrical and acoustic properties, and distributions of water and oil. Geostatistically, PBSs are correlated with PTSs. As such, NMR log-based subsurface formation pore typing is a useful tool in advanced formation evaluation.

However, certain assumptions may be observed to transform transverse relaxation time (T₂) into the surface area to volume ratio of the pore (S/V) based on PBSs or PSDs. For example, the transverse surface relaxivity (ρ₂) may be assumed to be 1.7 μm/s for carbonate rocks, although, this value may be influenced by the concentration and mineral form of paramagnetic minerals on the pore surface, the rock formations are in the presence of any fluids (e.g., wetting and nonwetting fluid phases), a type of fluid that may be present, and the like.

As such, calculating PSD from the NMR measurements may involve assuming that the corresponding rock formation includes pores having a single aspect ratio (AR) value or being circular pores. However, in natural rocks, the pore network may consist of multiple pore systems with varying ARs. Consequently, PSD should be analyzed for each pore system with a specific AR. Since NMR measurements alone do not provide information about pore shape, the present embodiments described herein employ sonic measurements to quantify the effects of AR on transferring transverse relaxation time (T₂) to PSD based on an elliptical tube model, and to derive individual PSDs from the transverse relaxation time (T₂) distribution for each pore system in multimodal pore systems.

### Monomodal Pore Networks

For monomodal pore systems, the derivation of PSD from NMR measurements (e.g., transverse relaxation time T₂ distribution) may be performed based on equations (3)-(6) provided below.

$$\underline{α} = \frac{b}{a} \qquad ( 3 )$$

$$p = 4 a * E ( 1 - {\underline{α}}^{2} ) \qquad ( 4 )$$

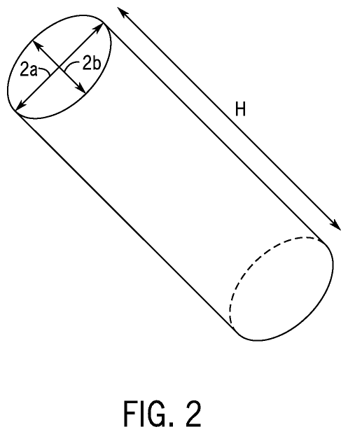

Equations (3) to (6) are used to derive semi-long axis a for each T₂ value, using the corresponding AR (α) and surface relaxivity (ρ₂) for the elliptical tube model depicted in FIG. 2. In addition, p corresponds to the perimeter of ellipse, and

$$E ( m ) = {\int }_{0}^{\frac{π}{2}} \sqrt{1 - {m ( sin t )}^{2}} d t$$

is the complete elliptic integral of the second kind, which is

$$\frac{π}{2}$$

when m=0 and gradually decreases to 1.0 when m=1.

$$\frac{S}{V} = \frac{4 a * E ( 1 - {\underline{α}}^{2} ) * h}{π a b * h} = \frac{4 * E ( 1 - {\underline{α}}^{2} )}{π a \underline{α}} \qquad ( 5 )$$

$$a = \frac{4 {T}_{2} {ρ}_{2} * E ( 1 - {\underline{α}}^{2} )}{π \underline{α}} \qquad ( 6 )$$

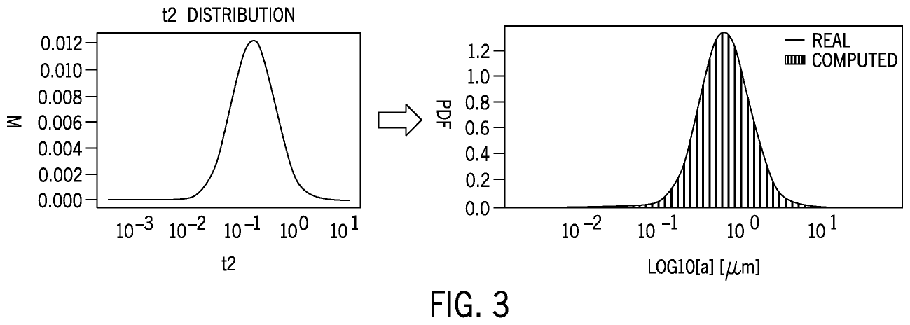

Each T₂ magnitude may then be normalized to calculate the probability density function (PDF) of semi-long axis a. To validate this process, a synthetic T₂ distribution may be generated using Equation (7) with a given PSD, AR (α), and surface relaxivity ρ₂. The PSD may then be calculated as described above and compared with the actual PSD, as depicted in FIG. 3.

$${T}_{2} = \frac{π a \underline{α}}{4 {ρ}_{2} * E ( 1 - {\underline{α}}^{2} )} \qquad ( 7 )$$

For example, assuming that there are 64 bins in the T₂ data ranging from 0.3 ms to 10,000 ms, the semi-long axis a value may be calculated from these T₂ bins using a specific AR (e.g., 0.15 for reference pores) and surface relaxivity ρ₂ according to Equation (7). The 64 probability values may be sampled according to the given PSD of the semi-long axis, thereby generating a synthetic T₂ distribution with 64 values of T₂ amplitude calculated after normalization by the total NMR porosity.

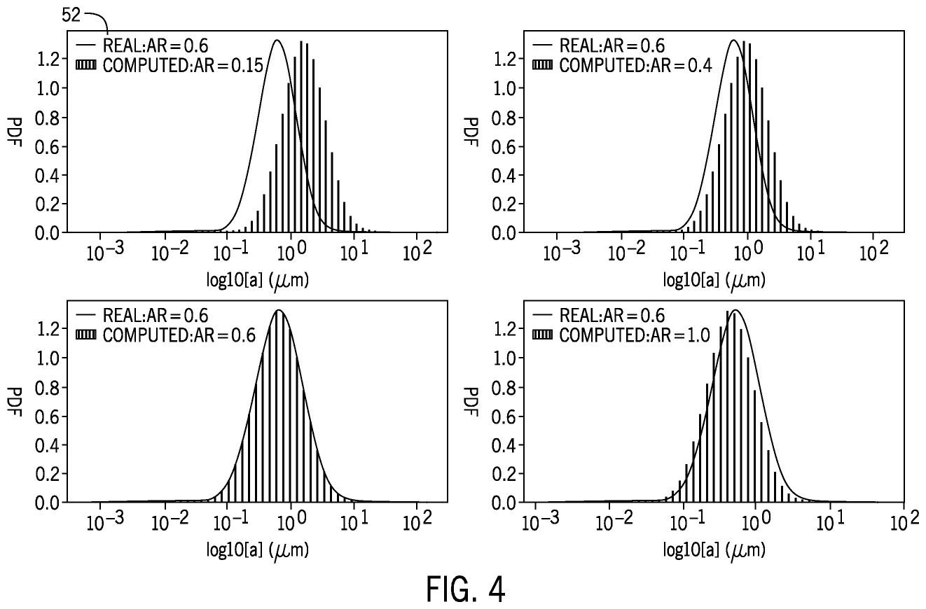

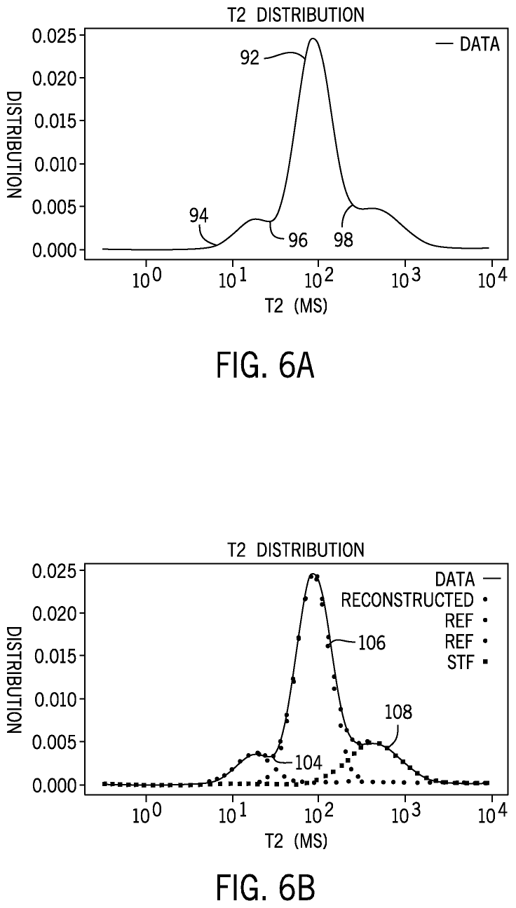

With the foregoing in mind, the effects of AR on the PSD derived from T₂ distribution are illustrated in FIG. 4. That is, curves 52 represent the true PSDs with an AR of 0.6, while the different depicted histograms show the calculated PSDs assuming ARs of 0.15, 0.4, 0.6 and 1.0, respectively. As shown in FIG. 6, using an incorrect AR can result in different PSDs from the same T₂ distribution. In the same manner, the effects of surface relaxivity (ρ₂) on PSD derivation from T₂ distribution influence the calculated PSDs in that an incorrect surface relaxivity ρ₂ value can also result in a different PSD derived from the same T₂ distribution. As such, the correct characterization of AR and pore surface relaxivity may contribute to determining the accurate PSD.

### Multimodal Pore Networks

For multimodal pore systems, each pore system may be associated with a respective pore AR. As such, it may be useful to derive individual PSDs for each pore system considering their specific AR. To achieve this, a computing system may receive NMR measurement data to determine a T₂ distribution and employ an inversion algorithm (e.g., the least squares method) to decompose T₂ distribution into one or more Gaussian distributions on a logarithmic scale of the T₂ distribution. As discussed above, the T₂ distribution provides an indication of an amount of fluid that may be present in pores of different sizes within the corresponding rock formation. As such, the T₂ distribution provides insight into the how pore sizes are distributed within the respective rock formation. By decomposing the T₂ distribution into one or more Gaussian distributions, the computing system may contain one or more different sized pores that may be part of the respective rock formation. To determine the different pore shapes (e.g., reference pores, crack pores, or stiff pores) for each respective pore system, the computing system may use corresponding sonic or acoustic measurements to assign each Gaussian distribution to an appropriate pore system. In some embodiments, a user may provide an indication or input to the computing system to assign each Gaussian distribution to an appropriate pore system. As such, in some embodiments, the computing system or the user input may attempt to assign the Gaussian distribution to the appropriate pore system by trial and error based on the sonic or acoustic data reconstruction. The computing system may then derive individual PSDs for each pore system based on the process described above for monomodal systems.

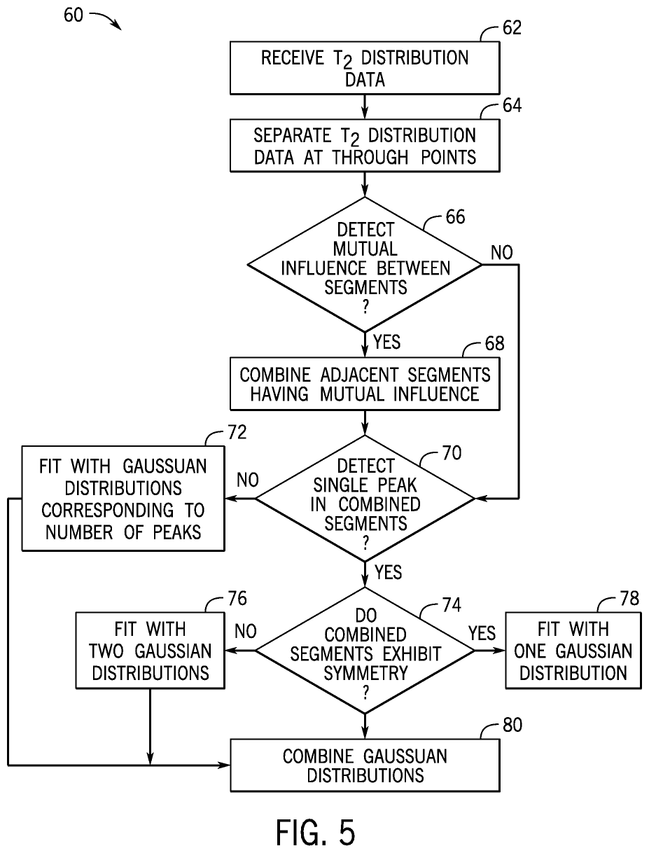

Keeping this in mind, FIG. 5 illustrates a flow chart of a method 60 for decomposing the T₂ distribution into one or more Gaussian distributions. Although the following description of the method 60 will be described as being performed in a particular order it should be understood that the method 60 may be performed in any suitable order. In addition, the method 60 is described below as being performed by a computing system. The computing system may correspond to any suitable computing device, such as a laptop, personal computer, server device, cloud computing device, mobile computing device, and the like. As such, the computing system may include similar components as described above with respect to the surface control system 28.

Referring now to FIG. 5, at block 62, the computing system may receive the T₂ distribution associated with a rock formation of the geological formation 14. The T₂ distribution may be generated based on NMR measurement data acquired from the NMR tools mentioned above. In some embodiments, the NMR measurement data may be acquired while in the borehole, but it should also be understood that the NMR measurement data may be acquired during core analysis in a laboratory setting. As discussed above, the T₂ distribution provides insight into how pore sizes are distributed within the respective rock formation.

At block 64, the computing system may separate the T₂ distribution into different segments. In some embodiments, for example, the computing system may analyze the T₂ distribution and identify one or more trough points that may be present in the T₂ distribution. The trough points may correspond to a local minimum or lowest point between peaks in a curve. By way of example, FIG. 6A illustrates an example curve 92 that corresponds to a T₂ distribution for a rock formation. As shown in FIG. 6A, the computing system may identify trough points 96 and 98 at various positions along the curve 92.

When separating the T₂ distribution into different segments, the computing system may combine adjacent segments if the magnitude of the trough point exceeds some threshold. These adjacent segments may experience some mutual influence between each other, as indicated by the relatively high trough point. By way of example, the measured T₂ distribution depicted with curve 92 of FIG. 6A may be separated into three inverted Gaussian distributions 104, 106, and 108 at trough points 96 and 98, as illustrated in FIG. 6B.

At block 66, the computing system may determine whether adjacent segments may influence each other based on the trough point analysis described above. If the computing system determines that no mutual influence exists between adjacent sections or that the trough points do not exceed the threshold, the computing system may proceed to block 70 to determine whether the T₂ distribution segments include a single peak, as will be discussed below. If, however, the computing system detects mutual influence between segments, the computing system may proceed to block 68.

At block 68, the computing system may combine the adjacent segments having the mutual influence. As such, the computing system may consider these adjacent segments together in view of their mutual influence. After combining the adjacent segments, the computing system may proceed to block 70 and determine whether the combined segments include a single peak.

If the computing system detects more than a single peak, the computing system may proceed to block 72 and fit a number of Gaussian distributions that corresponds to a number detected peaks. In some embodiments, the computing system may assume that the asymmetry arises from the mutual influence and fit the number of Gaussian distributions to the number of detected peaks. For example, referring to FIG. 6B, the computing system may fit three Gaussian distributions for the three inverted Gaussian distributions 104, 106, and 108.

Referring back to block 70 of FIG. 5, if the computing system detects a single peak, the computing system may proceed to block 74. At block 74, the computing system may determine whether the single T₂ distribution segment exhibits symmetry. If the computing system determines that the single T₂ distribution segment does not exhibit symmetry, the computing system may proceed to block 76 and fit the single T₂ distribution segment with two Gaussian distributions. Alternatively, if the single T₂ distribution segment that exhibits symmetry, the computing system may proceed to block 78 and fit the segment with one Gaussian distribution.

At block 80, the computing system may combine the number of Gaussian distributions determined at block 72 or fit at block 76. As a result, the computing system may have decomposition results of the combined Gaussian distributions. That is, the single or combined T₂ distribution segment may be broken into a sum of Gaussian components, such that each one represents a corresponding number of different pore sizes that may be present in the corresponding rock formation.

With the foregoing in mind, the computing system may still lack knowledge regarding the pore shape information of each of the different pores detected in the rock formation. As such, in some embodiments, the computing system may use other measurements, such as sonic or acoustic data (e.g., sonic logs), to determine the optimal assignment of individual Gaussian distributions to different pore systems with different pore ARs to reconstruct the measured acoustic data. For example, the computing system may employ a Differential Effective Medium (DEM) model and Gassmann fluid substitution equations to link sonic velocity to AR.

The geometric details of how rock constitutes may be arranged relative to each other may be useful to predict rock effective moduli. As such, in the DEM model, each pore type may be incrementally added to the rock matrix phase to construct the elastic moduli of a dry rock, as shown in Equations (8) to (11) below. In these equations, P and Q are geometric factors that are functions of AR (α).

$$( 1 - ϕ ) \frac{d}{d ϕ} [ {K}^{*} ( ϕ ) ] = ( {K}_{2} - {K}^{*} ) {P}^{( * 2 )} ( ϕ ) \qquad ( 8 )$$

$$( 1 - ϕ ) \frac{d}{d ϕ} [ {μ}^{*} ( ϕ ) ] = ( {μ}_{2} - {μ}^{*} ) {Q}^{( * 2 )} ( ϕ ) \qquad ( 9 )$$

$${P}^{*} = \frac{{K}_{m} + \frac{4}{3} {μ}_{i}}{{K}_{i} + \frac{4}{3} {μ}_{i} + π \underline{α} {β}_{m}} \qquad ( 10 )$$

$${Q}^{*} = \frac{1}{5} [ 1 + \frac{8 {μ}_{i}}{4 {μ}_{i} + π \underline{α} ( {μ}_{m} + 2 {β}_{m} )} + 2 \frac{{K}_{i} + \frac{2}{3} ( {μ}_{i} + {μ}_{m} )}{{K}_{i} + \frac{4}{3} {μ}_{i} + π \underline{α} {β}_{m}} ] \qquad ( 11 )$$

After determining the elastic moduli of a dry rock, the Gassmann fluid substitution equations as described in Equations 12a and 12b, may be used to simulate the effect of fluid and to acquire elastic moduli of the saturated rock.

$$\frac{{K}_{s a t}}{{K}_{0} - {K}_{s a t}} = \frac{{K}_{d r y}}{{K}_{0} - {K}_{d r y}} + \frac{{K}_{f l}}{ϕ ( {K}_{0} - {K}_{f l} )} \qquad ( 12 a )$$

$${μ}_{sat} = {μ}_{dry} \qquad ( 12 b )$$

Based on the equations provided above, the computing system may determine compressional velocity (V_{P}) and shear velocity (V_{S}), both of which may be linked to pore geometric information, such as the AR (α), as shown in Eq. 13.

$${V}_{P} = \sqrt{\frac{K + \frac{4}{3} μ}{ρ}} \qquad ( 13 a )$$

$${V}_{s} = \sqrt{\frac{μ}{ρ}} \qquad ( 13 b )$$

The subscripts m and i in the above equations refer to the background matrix and inclusions, dry and sat are for dry and saturated rock. K* and μ* are the effective bulk and shear moduli, with initial conditions K* (0)=K₁ and μ* (0)=μ₁. In addition, K₁ and μ₁ are the matrix bulk and shear moduli; K₂ and μ₂ are the bulk and shear moduli of the inclusion phase, respectively; dφ is the incremental change in porosity; P⁽*²⁾ and Q⁽*²⁾ are the geometrical factors depending on α of elliptical pores; and the superscript *2 on P and Q indicates that the factors are for an inclusion of material 2 in a background medium with effective moduli K* and μ*. In addition, K₀ is the bulk modulus of rock matrix and K_{fl} is the effective bulk modulus of pore fluid.

For describing carbonate rocks, the pore spaces may be categorized into three categories: microcracks, reference pores, and stiff pores. The microcracks (e.g., crack) may represent fractures with pore AR between 0.01-0.02 and <<1. The reference pores may represent interparticle pores with pore AR between 0.1-0.12, <1. The stiff pores may represent vugs, moldic, and intraframe pores with pore AR between 0.7-0.8, ≈ or →1.

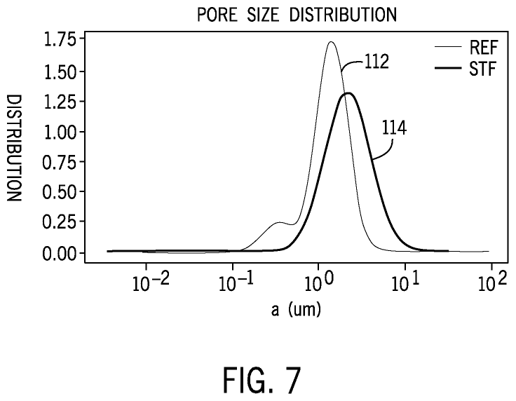

With this in mind, the computing system may assign each Gaussian distribution to a specific pore type, and thus an AR, such that the reconstructed sonic velocity may be calculated. The computing system may determine the pore type assignment for each Gaussian distribution by finding the combination that best fits the measured sonic velocity. By scanning and comparing a number of combinations and applying the DEM model and Gassmann fluid substitution, the computing system may identify the specific combination that best matches the sonic measurements acquired by the acoustic tools. As a result, the computing system may assign each separate Gaussian distribution to the appropriate pore system from the perspective of sonic measurements. The computing system may then determine the PSD for each pore system assuming that each respective pore system corresponds to a monomodal system and the characteristics of Equations (3)-(7) described above. In this way, individual PSDs for each pore system may be derived along with the volume fraction of the individual pore systems. For example, FIG. 7 illustrates a graph of individual PSDs for reference pores 112 with AR=0.15 and stiff pores 114 with AR=0.80 from assigned Gaussian distributions in FIG. 6B.

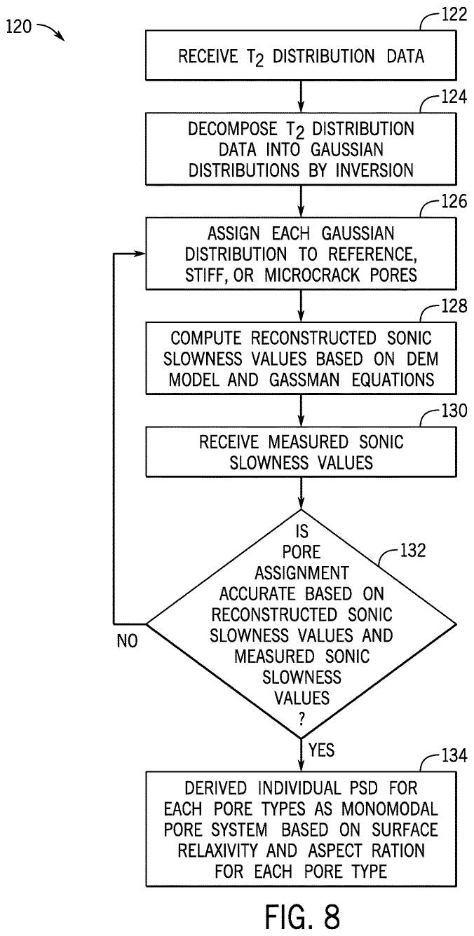

With the foregoing in mind, FIG. 8 illustrates a flow chart of a method 120 for determining individual PSDs for pore systems in a multimodal pore network. Although the following description of the method 120 is described in a particular order and being performed by the computing system, it should be understood that the method 120 may be performed in any suitable order and by any suitable computing system.

At block 122, the computing system may receive the T₂ distribution associated with a rock formation of the geological formation 14, as described above with reference to block 62 of FIG. 5. At block 124, the computing system may decompose the received T₂ distribution data into Gaussian distributions using inversion techniques as described above with reference to blocks 62-80 of FIG. 5.

At block 126, the computing system may assign each resulting Gaussian distribution to reference, stiff, or microcrack pores. In some embodiments, the computing system may analyze the Gaussian distribution and assign a pore type based on properties of the Gaussian distribution. In some embodiments, the computing system may scan each combination of the three pore types for assignment.

In any case, after assigning a pore to a Gaussian distribution, the computing system may proceed to block 128 and compute reconstructed sonic velocity or reconstructed sonic slowness values based on the DEM model and the Gassmann fluid substitution equations, as described above with reference to Equations (8)-(13).

At block 130, the computing system may receive measured sonic slowness values or acoustic signals from the acoustic tools described above (tools 12). In some embodiments, the measured sonic slowness values or acoustic signals may be acquired while in the borehole, but it should also be understood that the measured sonic slowness values or acoustic signals may be acquired during core analysis in a laboratory setting.

At block 132, the computing system may determine whether the pore type assignment made to each respective Gaussian distribution selected at block 126 is accurate based on the reconstructed slowness values and the measured slowness values. That is, the computing system may compare the difference between the two values and determine that the assignment is accurate if the difference is less than some threshold (e.g., value, percentage). If the assignment is not accurate, the computing system may return to block 126 and modify the assignment of the pore type to a respective Gaussian distribution. If, however, the assignment is determined to be accurate, the computing system may proceed to block 134.

At block 134, the computing system may derive the individual PSD for each pore type as a monomodal pore system based on the surface relaxivity and AR for each respective pore type. That is, the computing system may determine the PSD for each pore system assuming that each respective pore system corresponds to a monomodal system and the characteristics of Equations (3)-(7) described above.

The technical effect of the disclosed embodiments includes determining accurate individual PSDs for multimodal pore systems with different ARs. That is, the present embodiments provide an improved technique for calculating PSD from T₂ distribution considering that different parts of the pore network could have different AR. Indeed, the present embodiments use T₂ distribution data acquired by NMR tools and acoustic data acquired by acoustic tools to predict the PSDs in the rock formation. By performing the techniques described herein, the present embodiments provide the practical application of efficiently computing the PSDs using limited datasets, such as the T₂ distribution data and the acoustic data, as opposed to acquiring a core sample and physically testing the core sample to assess the PSDs. The present embodiments may decompose the T₂ distribution into one or more Gaussian distributions and then assign each Gaussian distribution to the appropriate pore type and corresponding AR by integrating sonic measurements and applying the DEM model and Gassmann fluid substitution. In this way, the present embodiments may determine the PSDs for a rock formation in real time based on T₂ distribution and acoustic data. In some embodiments, the determined PSDs may be used to modify drilling operations, data acquisition operations, fracturing operations, completion operations, recovery operations, reservoir simulation operations, and the like. In addition, the present embodiments provide a practical application in improving the accuracy and speed in which rock formations are characterized for reservoir analysis.

The subject matter described in detail above may be defined by one or more clauses, as set forth below.

A method, comprising receiving, via a processing system, transverse relaxation time (T₂) distribution data associated with a geological formation, wherein the T₂ distribution data is acquired by a nuclear magnetic resonance (NMR) tool; decomposing, via the processing system, the T₂ distribution data into one or more Gaussian distributions using one or more inversion techniques; computing, via the processing system, one or more reconstructed acoustic values associated with the geological formation based on a first Gaussian distribution of the one or more Gaussian distributions and a first pore type; receiving, via the processing system, one or more measured acoustic values associated with the geological formation, wherein the one or more measured acoustic values are acquired by one or more acoustic tools; determining, via the processing system, that the first pore type corresponds to the first Gaussian distribution based on the one or more reconstructed acoustic values and the one or more measured acoustic values; and in response to determining that the first pore type corresponds to the first Gaussian distribution, determining, via the processing system, a pore size distribution (PSD) for the first Gaussian distribution based on an aspect ratio associated with the first pore type.

The method of any preceding clause, comprising in response to determining that the first pore type does not correspond to the first Gaussian distribution, computing, via the processing system, one or more additional reconstructed acoustic values associated with the geological formation based on the first Gaussian distribution and a second pore type; determining, via the processing system, that the second pore type corresponds to the first Gaussian distribution based on the one or more reconstructed acoustic values and the one or more measured acoustic values; and in response to determining that the second pore type corresponds to the first Gaussian distribution, determining, via the processing system, the PSD for the first Gaussian distribution based on an additional aspect ratio associated with the second pore type.

The method of any preceding clause, wherein decomposing the T₂ distribution data into the one or more Gaussian distributions comprises: separating the T₂ distribution data into two or more T₂ segments based on one or more trough points of the T₂ distribution data; combining adjacent segments of the two or more T₂ segments to generate a combined T₂ distribution segment based on a presence of mutual influence between the adjacent segments; fitting a number of Gaussian distributions based on a number of peaks present in the combined T₂ distribution segment; and combining the number of Gaussian distributions.

The method of any preceding clause, wherein the one or more reconstructed acoustic values comprise sonic slowness values.

The method of any preceding clause, wherein the first pore type corresponds to the first Gaussian distribution based on the one or more reconstructed acoustic values being within a threshold of the one or more measured acoustic values.

The method of any preceding clause, wherein the first pore type comprises a microcrack pore, a reference pore, or a stiff pore.

The method of any preceding clause, comprising iteratively computing the one or more reconstructed acoustic values based on the first Gaussian distribution a plurality of pore type until the one or more reconstructed acoustic values are within a threshold of the one or more measured acoustic values.

A system, comprising: a computing system configured to perform operations comprising: receiving transverse relaxation time (T₂) distribution data associated with a geological formation, wherein the T₂ distribution data is acquired by a nuclear magnetic resonance (NMR) tool; decomposing the T₂ distribution data into one or more Gaussian distributions using one or more inversion techniques; computing one or more reconstructed acoustic values associated with the geological formation based on a first Gaussian distribution of the one or more Gaussian distributions and a first pore type; receiving one or more measured acoustic values associated with the geological formation, wherein the one or more measured acoustic values are acquired by one or more acoustic tools; determining that the first pore type corresponds to the first Gaussian distribution based on the one or more reconstructed acoustic values and the one or more measured acoustic values; and in response to determining that the first pore type corresponds to the first Gaussian distribution, determining a pore size distribution (PSD) for the first Gaussian distribution based on an aspect ratio associated with the first pore type.

The system of any preceding clause, wherein the computing system is configured to perform additional operations comprising: in response to determining that the first pore type does not correspond to the first Gaussian distribution, computing one or more additional reconstructed acoustic values associated with the geological formation based on the first Gaussian distribution and a second pore type; determining that the second pore type corresponds to the first Gaussian distribution based on the one or more reconstructed acoustic values and the one or more measured acoustic values; and in response to determining that the second pore type corresponds to the first Gaussian distribution, determining the PSD for the first Gaussian distribution based on an additional aspect ratio associated with the second pore type.

The system of any preceding clause, wherein decomposing the T₂ distribution data into the one or more Gaussian distributions comprises: separating the T₂ distribution data into two or more T₂ segments based on one or more trough points of the T₂ distribution data; combining adjacent segments of the two or more T₂ segments to generate a combined T₂ distribution segment based on a presence of mutual influence between the adjacent segments; fitting a number of Gaussian distributions based on a number of peaks present in the combined T₂ distribution segment; and combining the number of Gaussian distributions.

The system of any preceding clause, wherein the one or more reconstructed acoustic values comprise sonic slowness values.

The system of any preceding clause, wherein the first pore type corresponds to the first Gaussian distribution based on the one or more reconstructed acoustic values being within a threshold of the one or more measured acoustic values.

The system of any preceding clause, wherein the first pore type comprises a microcrack pore, a reference pore, or a stiff pore.

The system of any preceding clause, wherein the computing system is configured to perform additional operations comprising iteratively computing the one or more reconstructed acoustic values based on the first Gaussian distribution a plurality of pore type until the one or more reconstructed acoustic values are within a threshold of the one or more measured acoustic values.

A non-transitory computer-readable medium comprising computer-executable instructions that, when executed, are configured to cause a processing system to perform operations comprising: receiving transverse relaxation time (T₂) distribution data associated with a geological formation, wherein the T₂ distribution data is acquired by a nuclear magnetic resonance (NMR) tool disposed; decomposing the T₂ distribution data into one or more Gaussian distributions using one or more inversion techniques; computing one or more reconstructed acoustic values associated with the geological formation based on a first Gaussian distribution of the one or more Gaussian distributions and a first pore type; receiving one or more measured acoustic values associated with the geological formation, wherein the one or more measured acoustic values are acquired by one or more acoustic tools; determining that the first pore type corresponds to the first Gaussian distribution based on the one or more reconstructed acoustic values and the one or more measured acoustic values; and in response to determining that the first pore type corresponds to the first Gaussian distribution, determining a pore size distribution (PSD) for the first Gaussian distribution based on an aspect ratio associated with the first pore type.

The non-transitory computer-readable medium of any preceding clause, wherein the computer-executable instructions are configured to cause the processing system to perform additional operations comprising: in response to determining that the first pore type does not correspond to the first Gaussian distribution, computing one or more additional reconstructed acoustic values associated with the geological formation based on the first Gaussian distribution and a second pore type; determining that the second pore type corresponds to the first Gaussian distribution based on the one or more reconstructed acoustic values and the one or more measured acoustic values; and in response to determining that the second pore type corresponds to the first Gaussian distribution, determining the PSD for the first Gaussian distribution based on an additional aspect ratio associated with the second pore type.

The non-transitory computer-readable medium of any preceding clause, wherein the computer-executable instructions that cause the processing system to decompose the T₂ distribution data into the one or more Gaussian distributions comprises additional computer-executable instructions configured to cause the processing system to perform additional operations comprising: separating the T₂ distribution data into two or more T₂ segments based on one or more trough points of the T₂ distribution data; combining adjacent segments of the two or more T₂ segments to generate a combined T₂ distribution segment based on a presence of mutual influence between the adjacent segments; fitting a number of Gaussian distributions based on a number of peaks present in the combined T₂ distribution segment; and combining the number of Gaussian distributions.

The non-transitory computer-readable medium of any preceding clause, wherein the one or more reconstructed acoustic values comprise sonic slowness values.

The non-transitory computer-readable medium of any preceding clause, wherein the first pore type corresponds to the first Gaussian distribution based on the one or more reconstructed acoustic values being within a threshold of the one or more measured acoustic values.

The non-transitory computer-readable medium of any preceding clause, wherein the NMR tool, the one or more acoustic tools, or both are disposed in a borehole, used in a core analysis laboratory associated with the geological formation, or both.

The foregoing description, for purpose of explanation, has been described with reference to specific embodiments. However, the illustrative discussions above are not intended to be exhaustive or to limit the disclosure to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principals of the disclosure and its practical applications, to thereby enable others skilled in the art to best utilize the disclosure and various embodiments with various modifications as are suited to the particular use contemplated.

Finally, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

1. A method, comprising:
receiving, via a processing system, transverse relaxation time (T₂) distribution data associated with a geological formation, wherein the T₂ distribution data is acquired by a nuclear magnetic resonance (NMR) tool;
decomposing, via the processing system, the T₂ distribution data into one or more Gaussian distributions using one or more inversion techniques;
computing, via the processing system, one or more reconstructed acoustic values associated with the geological formation based on a first Gaussian distribution of the one or more Gaussian distributions and a first pore type;
receiving, via the processing system, one or more measured acoustic values associated with the geological formation, wherein the one or more measured acoustic values are acquired by one or more acoustic tools;
determining, via the processing system, that the first pore type corresponds to the first Gaussian distribution based on the one or more reconstructed acoustic values and the one or more measured acoustic values; and
in response to determining that the first pore type corresponds to the first Gaussian distribution, determining, via the processing system, a pore size distribution (PSD) for the first Gaussian distribution based on an aspect ratio associated with the first pore type.

2. The method of claim 1, comprising:
in response to determining that the first pore type does not correspond to the first Gaussian distribution, computing, via the processing system, one or more additional reconstructed acoustic values associated with the geological formation based on the first Gaussian distribution and a second pore type;
determining, via the processing system, that the second pore type corresponds to the first Gaussian distribution based on the one or more reconstructed acoustic values and the one or more measured acoustic values; and
in response to determining that the second pore type corresponds to the first Gaussian distribution, determining, via the processing system, the PSD for the first Gaussian distribution based on an additional aspect ratio associated with the second pore type.

3. The method of claim 1, wherein decomposing the T₂ distribution data into the one or more Gaussian distributions comprises:
separating the T₂ distribution data into two or more T₂ segments based on one or more trough points of the T₂ distribution data;
combining adjacent segments of the two or more T₂ segments to generate a combined T₂ distribution segment based on a presence of mutual influence between the adjacent segments;
fitting a number of Gaussian distributions based on a number of peaks present in the combined T₂ distribution segment; and
combining the number of Gaussian distributions.

4. The method of claim 1, wherein the one or more reconstructed acoustic values comprise sonic slowness values.

5. The method of claim 1, wherein the first pore type corresponds to the first Gaussian distribution based on the one or more reconstructed acoustic values being within a threshold of the one or more measured acoustic values.

6. The method of claim 1, wherein the first pore type comprises a microcrack pore, a reference pore, or a stiff pore.

7. The method of claim 1, comprising iteratively computing the one or more reconstructed acoustic values based on the first Gaussian distribution a plurality of pore type until the one or more reconstructed acoustic values are within a threshold of the one or more measured acoustic values.

8. A system, comprising:
a computing system configured to perform operations comprising:
receiving transverse relaxation time (T₂) distribution data associated with a geological formation, wherein the T₂ distribution data is acquired by a nuclear magnetic resonance (NMR) tool;
decomposing the T₂ distribution data into one or more Gaussian distributions using one or more inversion techniques;
computing one or more reconstructed acoustic values associated with the geological formation based on a first Gaussian distribution of the one or more Gaussian distributions and a first pore type;
receiving one or more measured acoustic values associated with the geological formation, wherein the one or more measured acoustic values are acquired by one or more acoustic tools;
determining that the first pore type corresponds to the first Gaussian distribution based on the one or more reconstructed acoustic values and the one or more measured acoustic values; and
in response to determining that the first pore type corresponds to the first Gaussian distribution, determining a pore size distribution (PSD) for the first Gaussian distribution based on an aspect ratio associated with the first pore type.

9. The system of claim 8, wherein the computing system is configured to perform additional operations comprising:
in response to determining that the first pore type does not correspond to the first Gaussian distribution, computing one or more additional reconstructed acoustic values associated with the geological formation based on the first Gaussian distribution and a second pore type;
determining that the second pore type corresponds to the first Gaussian distribution based on the one or more reconstructed acoustic values and the one or more measured acoustic values; and
in response to determining that the second pore type corresponds to the first Gaussian distribution, determining the PSD for the first Gaussian distribution based on an additional aspect ratio associated with the second pore type.

10. The system of claim 8, wherein decomposing the T₂ distribution data into the one or more Gaussian distributions comprises:
separating the T₂ distribution data into two or more T₂ segments based on one or more trough points of the T₂ distribution data;
combining adjacent segments of the two or more T₂ segments to generate a combined T₂ distribution segment based on a presence of mutual influence between the adjacent segments;
fitting a number of Gaussian distributions based on a number of peaks present in the combined T₂ distribution segment; and
combining the number of Gaussian distributions.

11. The system of claim 8, wherein the one or more reconstructed acoustic values comprise sonic slowness values.

12. The system of claim 8, wherein the first pore type corresponds to the first Gaussian distribution based on the one or more reconstructed acoustic values being within a threshold of the one or more measured acoustic values.

13. The system of claim 8, wherein the first pore type comprises a microcrack pore, a reference pore, or a stiff pore.

14. The system of claim 8, wherein the computing system is configured to perform additional operations comprising iteratively computing the one or more reconstructed acoustic values based on the first Gaussian distribution a plurality of pore type until the one or more reconstructed acoustic values are within a threshold of the one or more measured acoustic values.

15. A non-transitory computer-readable medium comprising computer-executable instructions that, when executed, are configured to cause a processing system to perform operations comprising:
receiving transverse relaxation time (T₂) distribution data associated with a geological formation, wherein the T₂ distribution data is acquired by a nuclear magnetic resonance (NMR) tool disposed;
decomposing the T₂ distribution data into one or more Gaussian distributions using one or more inversion techniques;
computing one or more reconstructed acoustic values associated with the geological formation based on a first Gaussian distribution of the one or more Gaussian distributions and a first pore type;
receiving one or more measured acoustic values associated with the geological formation, wherein the one or more measured acoustic values are acquired by one or more acoustic tools;
determining that the first pore type corresponds to the first Gaussian distribution based on the one or more reconstructed acoustic values and the one or more measured acoustic values; and
in response to determining that the first pore type corresponds to the first Gaussian distribution, determining a pore size distribution (PSD) for the first Gaussian distribution based on an aspect ratio associated with the first pore type.

16. The non-transitory computer-readable medium of claim 15, wherein the computer-executable instructions are configured to cause the processing system to perform additional operations comprising:
in response to determining that the first pore type does not correspond to the first Gaussian distribution, computing one or more additional reconstructed acoustic values associated with the geological formation based on the first Gaussian distribution and a second pore type;
determining that the second pore type corresponds to the first Gaussian distribution based on the one or more reconstructed acoustic values and the one or more measured acoustic values; and
in response to determining that the second pore type corresponds to the first Gaussian distribution, determining the PSD for the first Gaussian distribution based on an additional aspect ratio associated with the second pore type.

17. The non-transitory computer-readable medium of claim 15, wherein the computer-executable instructions that cause the processing system to decompose the T₂ distribution data into the one or more Gaussian distributions comprises additional computer-executable instructions configured to cause the processing system to perform additional operations comprising:
separating the T₂ distribution data into two or more T₂ segments based on one or more trough points of the T₂ distribution data;
combining adjacent segments of the two or more T₂ segments to generate a combined T₂ distribution segment based on a presence of mutual influence between the adjacent segments;
fitting a number of Gaussian distributions based on a number of peaks present in the combined T₂ distribution segment; and
combining the number of Gaussian distributions.

18. The non-transitory computer-readable medium of claim 15, wherein the one or more reconstructed acoustic values comprise sonic slowness values.

19. The non-transitory computer-readable medium of claim 15, wherein the first pore type corresponds to the first Gaussian distribution based on the one or more reconstructed acoustic values being within a threshold of the one or more measured acoustic values.

20. The non-transitory computer-readable medium of claim 15, wherein the NMR tool, the one or more acoustic tools, or both are disposed in a borehole, used in a core analysis laboratory associated with the geological formation, or both.
